(19) United States
(12) Patent Application Publication
(10) Pub. No.: US 2021/0050294 A1
(43) Pub. Date: Feb. 18, 2021

(54) FAN-OUT CHIP PACKAGE ASSEMBLY AND FAN-OUT BOTTOM PACKAGE WITH FINE PITCH SILICON THROUGH VIA

(71) Applicant: POWERTECH TECHNOLOGY INC., HSINCHU COUNTY (TW)

(72) Inventors: Pei-Chun Tsai, HSINCHU COUNTY (TW); Hung-Hsin Hsu, HSINCHU COUNTY (TW); Shang-Yu Chang Chien, HSINCHU COUNTY (TW); Nan-Chun Lin, HSINCHU COUNTY (TW)

(21) Appl. No.: 16/703,809

(22) Filed: Dec. 4, 2019

(30) Foreign Application Priority Data
Aug. 15, 2019 (TW) 108129114

(51) Int. Cl. H01L 23/535; H01L 23/498; H01L 23/00; H01L 25/065

(52) U.S. Cl. CPC H01L 23/535; H01L 23/49861; H01L 23/49811; H01L 2225/06541; H01L 24/05; H01L 25/065; H01L 2224/02379; H01L 23/49833

(57) ABSTRACT

A fan-out chip package assembly with fine pitch silicon through via uses one or more silicon interposers in the bottom package as interconnections between the top package and the substrate. The one or more partially distributed silicon interposers may be disposed in the same layer of the bottom semiconductor die according to the design requirement of the fan-out contact pads of the top package, allowing more design freedom of the top high level chips.

### BACKGROUND OF THE INVENTION

### 1. Field of the Invention

The invention relates to a package structure, and more particularly, to a fan-out chip package assembly using silicon interposer as partial through silicon via.

### 2. Description of the Prior Art

High level chips have been in increasing demand for product requirements like small size, high I/O count, high thermo performance, and low noise. Back-end processes such as packaging also follow the direction towards reducing the overall package size or integrating more functions in the same chip area and increase the I/O count. It is certainly a trendy development of IC with high I/O count and lowering of the size of contact pads and pitch.

For multilayer package structure, copper pillar is commonly used as connection between lower package and upper package. Since the height of the connecting copper pillars is directly related to the thickness of the package assembly, which should be maintained above a certain thickness considering the requirement of heat dissipation and noise control of high level chips, the copper pillars also have its height limitation. As the current packaging process has the copper pillars grow before molding, higher copper pillars should come with larger diameter for stability of the structure. Larger diameter design of copper pillars means direct limitation to the pitch of I/O pins, I/O count, and the specification of the upper package.

To sum up, the thickness of the chip determines the height of the copper pillars, thereby introducing the lowest limit of the pitch of I/O pins and physical limitation of the fan-out pins of fan-out packaging structure, the I/O count, and design of the upper package structure.

### SUMMARY OF THE INVENTION

The embodiments of the invention provide a fan-out chip package assembly and a fan-out package with fine pitch silicon through via to solve the above-mentioned problem.

According to an embodiment of the invention, a fan-out chip package assembly with fine pitch silicon through via is disposed on a substrate. The fan-out chip package assembly includes a first package and a second package. The first package includes a semiconductor chip and a silicon interposer. The semiconductor chip and the silicon interposer are embedded and packaged in a molding layer. The first package has a bottom surface and a top surface opposite with each other. The second package is disposed on the top surface of the first package. The first package is disposed on the substrate via the bottom surface and a plurality of contacts of the semiconductor chip is electrically connected to the substrate, and a plurality of contacts of the second package is electrically connected to the substrate via the silicon interposer.

According to another embodiment of the invention, a fan-out package with fine pitch silicon through via is disposed on a substrate. The fan-out package includes a semiconductor chip and a silicon interposer. The semiconductor chip and the silicon interposer are embedded and packaged in a molding layer. The fan-out package has a bottom surface and a top surface opposite with each other. The fan-out package is disposed on the substrate via the bottom surface and a plurality of contacts of the semiconductor chip is electrically connected to the substrate.

According to the embodiments of the invention, the silicon interposer is disposed in the first package with through silicon via (TSV) and is electrically connected with the substrate and the second package.

According to the embodiments of the invention, the silicon interposer is partially disposed at a side of the semiconductor chip.

According to the embodiments of the invention, the semiconductor chip and the silicon interposer are adjacent to each other in the same molding layer.

According to the embodiments of the invention, the silicon interposer includes one or more connection wirings connected between the second package and the substrate through one or more corresponding contact pads.

According to the embodiments of the invention, the silicon interposer is pre-made by silicon procedure before molding.

According to the embodiments of the invention, the fan-out chip package assembly further includes at least one redistribution layer disposed between the bottom surface of the first package and the substrate. The at least one redistribution layer includes a plurality of contact pads and the plurality of contacts of the second package, through the silicon interposer, along with the plurality of contacts of the semiconductor chip are connected to the substrate via the plurality of contact pads.

The fan-out chip package assembly according to the embodiments of the invention utilizes silicon interposers with fine pitch as through silicon via (TSV) packaging, facilitating high area density and allowable I/O numbers of the top package and promoting functions that can be included given same unit chip area.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration showing an embodiment of the first package of the chip package assembly according to the invention.

FIG. 2 is an illustration showing an embodiment of the first package and the second package of the chip package assembly.

FIG. 3 is an illustration showing the fan-out chip assembly package with fine pitch silicon through via disposed on a substrate according to the invention.

### DETAILED DESCRIPTION

Certain terms are used throughout the following description and claims to refer to particular system components. As one skilled in the art will appreciate, manufacturers may refer to a component by different names. In the following discussion and in the claims, the terms “include” and “comprise” are used in an open-ended fashion. Also, the term “couple” is intended to mean either an indirect or direct electrical/mechanical connection. Thus, if a first device is coupled to a second device, that connection may be through a direct electrical/mechanical connection, or through an indirect electrical/mechanical connection via other devices and connections.

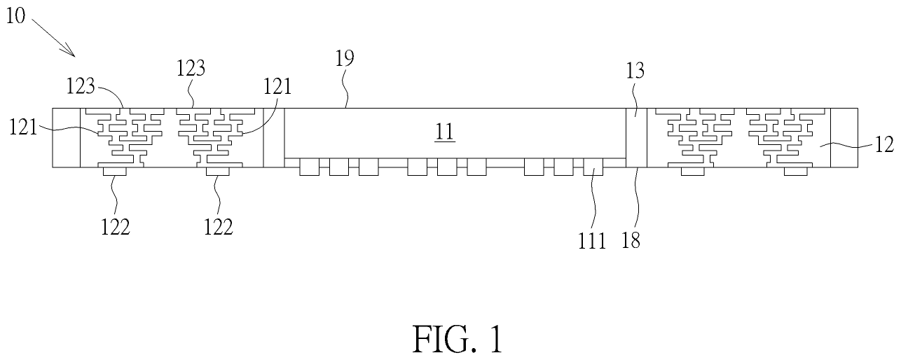

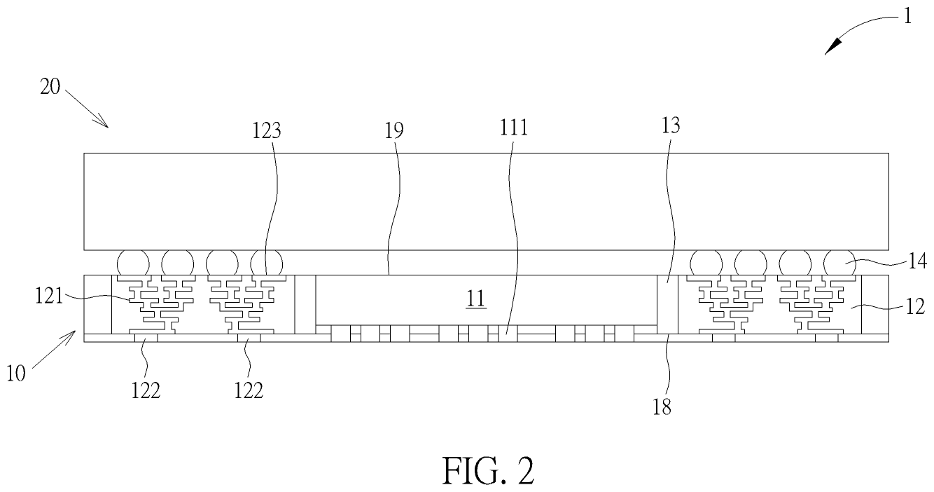

Please refer to FIG. 1 and FIG. 2. FIG. 1 is an illustration showing an embodiment of the first package of the chip package assembly according to the invention and FIG. 2 is an illustration showing an embodiment of the first package and the second package of the chip package assembly. A fan-out chip package assembly 1 with fine pitch silicon through via is based on fan-out structure to replace a portion of or all of the copper-pillar-based connection for double-layered packages or multi-layered packages. In FIG. 1, the first package 10 includes at least a semiconductor chip 11 and at least a silicon interposer 12. In other embodiments of the invention, the first package 10 can includes one or more homogeneous or heterogeneous semiconductor chips 11 and one or more silicon interposers 12 partially disposed at a side or at the surrounding of the semiconductor chips 11. The semiconductor chips 11 and the silicon interposers 12 are later embedded and packaged in a same molding layer 13. In other words, the semiconductor chips 11 and the silicon interposers 12 according to the invention are adjacent to each other in the same molding layer 13.

The molded first package 10 has a bottom surface 18 and a top surface 19 opposite with each other. The second package 20 (or the top package) is disposed on the top surface 19 of the first package 10 (or a fan-out package itself). In other embodiments, another package(s) can be further stacked on top of the second package 20 and have between-layer partial or all connections through the silicon interposers. The illustrations and embodiments provided in the invention should not be regarded as limitations. The silicon interposer 12 is disposed in the first package 10 with through silicon via (TSV) package procedure.

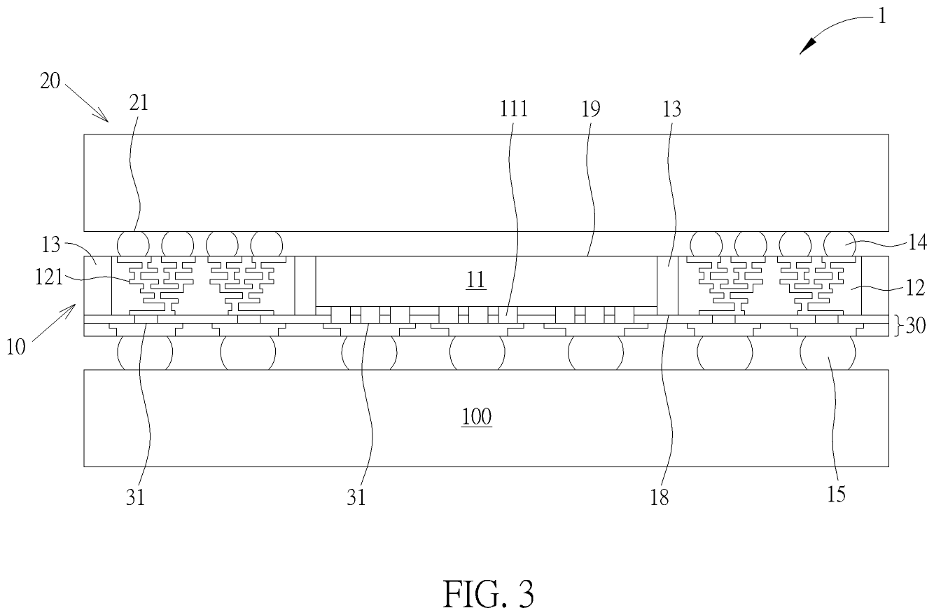

Please also refer to FIG. 3, which is an illustration showing the fan-out chip assembly package with fine pitch silicon through via disposed on a substrate according to the invention. The first package 10 is disposed on a substrate 100 via the bottom surface 18. The silicon interposers 12 at the same layer as the semiconductor chip 11 electrically connect between the second package 20 and the substrate 100. The silicon interposers 12 pre-made by silicon procedure before molding is capable of providing one or more connection wirings 121 with extremely fine pitch and line width. Through one or more corresponding contact pads 123, 122 and soldering bumps 14, 15, the upper layer second package 20 can be electrically connected to the lower layer substrate 100. The plurality of contacts 21 of the second package 20 stacked on the first package 10 can be electrically connected to the substrate 100 via the silicon interposer 12. Furthermore, a plurality of contacts 111 of the semiconductor chip 11 in the first package 10 is also electrically connected to the substrate 100.

Since the second package 20 is connected to the substrate 100 using silicon interposers 12, the limit of conventional copper-pillar-based connection at the design level of second package 20 is broken for far flexible pitch of contacts and I/O count deployment. In other words, the plurality of fan-out contacts 21 of the chips (one or more homogeneous or heterogeneous semiconductor chips as well) of the second package 20 is able to be configured to have pitch as fine as possible, less than 150 um and preferably less than 75 um for example, and only the design need is the limit.

Please keep referring to FIG. 3. The fan-out chip package assembly 1 may further utilize one or more redistribution layers 30 (RDL) between the bottom surface 18 of the first package 10 and the substrate 100. The one or more redistribution layers 30 includes a plurality of contact pads 31, while the plurality of contacts 21 of the second package 20, through the silicon interposers 12, and the plurality of contacts 111 of the semiconductor chip 11 are connected to the substrate 100 via the plurality of contact pads 31.

The fan-out chip package assembly and fan-out package provided in the invention use one or more silicon interposers in the bottom package as interconnections between the top package and the substrate. The one or more partially distributed silicon interposers may be disposed at the same layer of and adjacent to the bottom semiconductor die according to the design requirement of the fan-out contact pads of the top package, allowing more design freedom of the top high level chips.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fan-out chip package assembly with fine pitch silicon through via, disposed on a substrate, the fan-out chip package assembly comprising:
a first package comprising a semiconductor chip and a silicon interposer, the semiconductor chip and the silicon interposer embedded and packaged in a molding layer, the first package having a bottom surface and a top surface opposite with each other; and
a second package disposed on the top surface of the first package;
wherein the first package is disposed on the substrate via the bottom surface and a plurality of contacts of the semiconductor chip is electrically connected to the substrate, and a plurality of contacts of the second package is electrically connected to the substrate via the silicon interposer.

2. The fan-out chip package assembly of claim 1, wherein the silicon interposer is disposed in the first package with through silicon via (TSV) and is electrically connected with the substrate and the second package.

3. The fan-out chip package assembly of claim 1, wherein the silicon interposer is partially disposed at a side of the semiconductor chip.

4. The fan-out chip package assembly of claim 1, wherein the semiconductor chip and the silicon interposer are adjacent to each other in the same molding layer.

5. The fan-out chip package assembly of claim 1, wherein the silicon interposer comprises one or more connection wirings connected between the second package and the substrate through one or more corresponding contact pads.

6. The fan-out chip package assembly of claim 1, wherein the silicon interposer is pre-made by silicon procedure before molding.

7. The fan-out chip package assembly of claim 1, further comprising at least one redistribution layer disposed between the bottom surface of the first package and the substrate, the at least one redistribution layer comprising a plurality of contact pads, the plurality of contacts of the second package, through the silicon interposer, and the plurality of contacts of the semiconductor chip connected to the substrate via the plurality of contact pads.

8. A fan-out package with fine pitch silicon through via, disposed on a substrate, the fan-out package comprising a semiconductor chip and a silicon interposer, the semiconductor chip and the silicon interposer embedded and packaged in a molding layer, the fan-out package having a bottom surface and a top surface opposite with each other, the fan-out package disposed on the substrate via the bottom surface and a plurality of contacts of the semiconductor chip electrically connected to the substrate.

9. The fan-out package of claim 8, wherein a top package is disposed on the top surface of the fan-out package and a plurality of contacts of the top package is electrically connected to the substrate via the silicon interposer.

10. The fan-out package of claim 9, wherein the silicon interposer is disposed in the fan-out package with through silicon via (TSV) and is electrically connected with the substrate and the top package.

11. The fan-out package of claim 8, wherein the silicon interposer is partially disposed at a side of the semiconductor chip.

12. The fan-out package of claim 8, wherein the semiconductor chip and the silicon interposer are adjacent to each other in the same molding layer.

13. The fan-out package of claim 8, wherein the silicon interposer comprises one or more connection wirings.

14. The fan-out package of claim 8, wherein the silicon interposer is pre-made by silicon procedure before molding.

15. The fan-out package of claim 8, further comprising at least one redistribution layer disposed between the bottom surface and the substrate, the at least one redistribution layer comprising a plurality of contact pads, the plurality of contacts of the semiconductor chip connected to the substrate via the plurality of contact pads.
